(19) United States
(12) Patent Application Publication
(10) Pub. No.: US 2016/0122867 A1
(43) Pub. Date: May 5, 2016

(54) DEPOSITION METHOD FOR TUNGSTEN-CONTAINING FILM USING TUNGSTEN COMPOUND, AND PRECURSOR COMPOSITION FOR DEPOSITING TUNGSTEN-CONTAINING FILM, COMPRISING TUNGSTEN COMPOUND

(71) Applicant: UP CHEMICAL CO., LTD., Gyeonggi-do (KR)

(72) Inventors: Won Seok HAN, Anseong-si (KR); Beom-Sang YOO, Asan-si (KR); Hong-Joo LEE, Deojeon (KR)

(73) Assignee: UP CHEMICAL CO., LTD., Pyeongtaek-si, Gyeonggi-do, KR (KR)

(21) Appl. No.: 14/893,427

(22) PCT Filed: May 26, 2014
(86) PCT No.: PCT/KR2014/004666

§ 371 Date: Nov. 23, 2015

(30) Foreign Application Priority Data
May 24, 2013 (KR) 10-2013-0059238
May 26, 2014 (KR) 10-2014-0062800

(51) Int. Cl. C23C 16/18; C07F 11/00; C23C 16/455

(52) U.S. Cl. CPC C23C 16/18; C23C 16/45553; C07F 11/00

(57) ABSTRACT

The present disclosure relates to a deposition method for a tungsten-containing film using a tungsten compound and a precursor composition for depositing the tungsten-containing film including the tungsten compound.

### CROSS-REFERENCE TO RELATED APPLICATION

This application is a continuation of and claims benefit under 35 U.S.C. §371 of International Application No. PCT/KR2014/004666 filed on May 26, 2014, claiming the priority based on Korean Patent Application No. 10-2013-0059238 filed on May 24, 2013 and Korean Patent Application No. 10-2014-0062800 filed on May 26, 2014, the contents of all of which are incorporated herein by reference in their entirety.

### TECHNICAL FIELD

The present disclosure relates to a deposition method of a tungsten-containing film using a tungsten compound and a precursor composition including the tungsten compound for depositing the tungsten-containing film.

### BACKGROUND

In manufacturing a semiconductor device, tungsten (W)-containing film has been used for various uses. Typically, a tungsten-containing film is formed by a chemical vapor deposition (CVD) method or an atomic layer deposition (ALD) method. As a material for forming the tungsten-containing film, tungsten hexafluoride (WF₆) has been widely used.

However, as scaling-down of a semiconductor device has been progressed, it is necessary to form a tungsten-containing film using a tungsten material which does not contain fluorine. As a precursor for deposition without containing fluorine, various tungsten compounds have been known. However, the conventionally known tungsten compounds without containing fluorine have a problem that a deposited film contains a lot of nitrogen or oxygen, and, thus, the film may have undesirable film properties.

By way of example, as an organic metal precursor for forming a tungsten-containing film, a tungsten carbonyl compound (W(CO)₆) has been generally known. The carbonyl (CO) ligand contained in the compound is easily dissociated even at a low temperature. Thus, although it is advantageous in that a metal tungsten film can be deposited by pyrolysis at a low temperature without presence of an additional reacting gas, the properties of a tungsten layer may be deteriorated due to mixing of CO as a reaction product into the thermally deposited tungsten layer. As a result, the electrical conductivity of the tungsten layer may be decreased [Bing Luo and Wayne L. Gladfelte (2009), “Chapter 7. Chemical Vapor Deposition of Metals: W, Al, Cu and Ru” in Anthony C Jones and Michael L Hitchman (Eds.) “Chemical Vapour Deposition: Precursors”, (Page 322), Royal Society of Chemistry].

### DETAILED DESCRIPTION OF THE INVENTION

### Problems to be Solved by the Invention

Accordingly, the present disclosure provides a deposition method of a tungsten-containing film using a tungsten compound, and a precursor composition including the tungsten compound for depositing the tungsten-containing film.

However, problems to be solved by the present disclosure are not limited to the above-described problems. Although not described herein, other problems to be solved by the present disclosure can be clearly understood by those skilled in the art from the following descriptions.

### Means for Solving the Problems

In a first aspect of the present disclosure, there is provided a deposition method of a tungsten-containing film using a tungsten compound, including: contacting a gas including the tungsten compound represented by the following Chemical Formula 1 with a surface of a substrate:

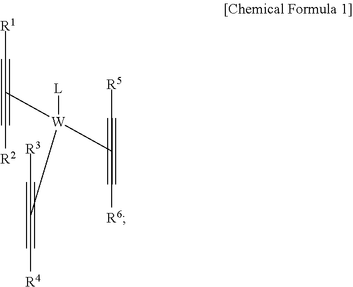

wherein in the above Chemical Formula 1,

each of R¹ to R⁶ independently includes H or a C₁₋₅ alkyl group,

L includes a non-cyclic or cyclic neutral ligand having a carbon number ranging from 0 to 5 and including 1 to 3 nitrogens or oxygens.

In a second aspect of the present disclosure, there is provided a precursor composition for depositing a tungsten-containing film, including: a tungsten compound represented by the above Chemical Formula 1.

### Effect of the Invention

According to the embodiments of the present disclosure, it is possible to form a tungsten-containing film using a deposition method of a tungsten-containing film using a tungsten compound containing an alkyne ligand, and a precursor composition including the tungsten compound for depositing the tungsten-containing film. According to some embodiments of the present disclosure, it is possible to form a tungsten-containing film using a tungsten compound containing an alkyne ligand through a chemical vapor deposition (CVD) or atomic layer deposition (ALD), and also possible to provide a composition containing the tungsten compound for depositing a film. In particular, according to the embodiments of the present disclosure, it is possible to form a tungsten-containing film with less nitrogen or oxygen impurities.

### BRIEF DESCRIPTION OF THE DRAWINGS

FIG. 1 is a thermogravimetric analysis (TGA) graph of a tungsten compound W(CO)(CH₃CH₂C≡CCH₂CH₃)₃ prepared according to Preparation Example 1 of the present disclosure;

FIG. 2 is a differential scanning calorimetry (DSC) graph of a tungsten compound W(CO)(CH₃CH₂C≡CCH₂CH₃)₃ prepared according to Preparation Example 1 of the present disclosure;

FIG. 3A to FIG. 3D provide cross-sectional scanning electron microscopic (SEM) images of tungsten-containing films formed at a temperature of 325° C. of a substrate according to Example 1 of the present disclosure;

FIG. 4A to FIG. 4D provide cross-sectional scanning electron microscopic (SEM) images of tungsten-containing films formed at a temperature of 350° C. of the substrate according to Example 1 of the present disclosure;

FIG. 5 provides an Auger analysis result of a tungsten-containing film formed using hydrogen (H₂) gas at a temperature of 350° C. of a substrate according to Example 2 of the present disclosure;

FIG. 6 provides an Auger analysis result of a tungsten-containing film formed using ammonia (NH₃) gas at a temperature of 350° C. of the substrate according to Example 2 of the present disclosure; and

FIG. 7 a thermogravimetric analysis (TGA) graph of a precursor composition for depositing a tungsten-containing film in each of the case where a stabilizing agent is added and the case where a stabilizing agent is not added according to Example 3 of the present disclosure.

### BEST MODE FOR CARRYING OUT THE INVENTION

Hereinafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the another element and a case that any other element exists between these two elements.

Further, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party.

Through the whole document, the term “step of” does not mean “step for”.

Through the whole document, the term “combination of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

Through the whole document, a phrase in the form “A and/or B” means “A or B, or A and B”.

Through the whole document of the present disclosure, the term “alkyl group” may include linear or branched saturated or unsaturated C₁₋₁₀ or C₁₋₅ alkyl groups, and may include, for example, methyl, ethyl, propyl, butyl, pentyl, hexyl, heptyl, octyl, nonyl, decyl, or possible isomers thereof, but may not be limited thereto.

Through the whole document of the present disclosure, the term “neutral ligand L” may include non-cyclic or cyclic compounds each having a carbon number ranging from 0 to 5 and including 1 to 3 hetero-atoms selected from nitrogens or oxygens, and may include, for example, a member selected from the group consisting of atoms or molecules having an unshared electron pair, CO, CS, NO, CO₂, CS₂, NH₃, H₂O, amine, ether, alkylnitrile, isocyanide, and derivatives thereof, but may not be limited thereto.

Through the whole document of the present disclosure, the term “coordinated bond” refers to the bond in which electrons for the bond formation are formally donated from only one of two atoms involved in the bond. Typically, a central metal at a center of a coordination compound such as a complex is bonded to a ligand around the central metal by the coordinated bond.

Hereinafter, embodiments of the present disclosure are described in detail, but the present disclosure may not be limited thereto.

In a first aspect of the present disclosure, there is provided a deposition method of a tungsten-containing film using a tungsten compound, including: contacting a gas including the tungsten compound represented by the following Chemical Formula 1 with a surface of a substrate:

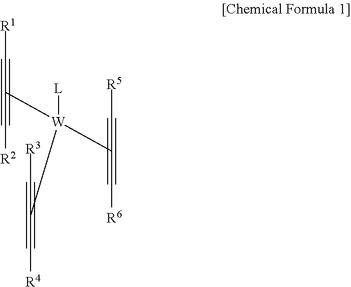

wherein in the above Chemical Formula 1,

each of R¹ to R⁶ independently includes H or a C₁₋₅ alkyl group,

L includes a non-cyclic or cyclic neutral ligand having a carbon number ranging from 0 to 5 and including 1 to 3 nitrogens or oxygens.

In an embodiment of the present disclosure, the C₁₋₅ alkyl group may include a member selected from the group consisting of methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neo-pentyl group, 3-pentyl group, and isomers thereof, but may not be limited thereto.

In an embodiment of the present disclosure, the L may include a member selected from the group consisting of carbon monoxide (CO), nitrogen monoxide (NO), and acetonitrile (CH₃CN), but may not be limited thereto.

In an embodiment of the present disclosure, the tungsten compound may include a member selected from the group consisting of W(CO)(HC≡CH)₃, W(CO)(CH₃C≡CCH₃)₃, W(CO)(CH₃CH₂C≡CCH₂CH₃)₃, W(CO)(CH₃(CH₂)₂C≡C(CH₂)₂CH₃)₃, W(CO)(HC≡CCH₃)₃, W(CO)(HC≡CCH₂CH₃)₃, W(CO)(HC≡C(CH₂)₂CH₃)₃, W(CO)(HC≡C(CH₂)₃CH₃)₃, W(CO)(HC≡C(CH₂)₄CH₃)₃, W(CO)(CH₃C≡CCH₂CH₃)₃, W(CO)(CH₃C≡C(CH₂)₂CH₃)₃, W(CO)(CH₃C≡C(CH₂)₃CH₃)₃, W(CO)(CH₃CH₂C≡C(CH₂)₂CH₃)₃, W(CO)(HC≡CCH(CH₃)₂)₃, W(CO)(HC≡CC(CH₃)₃)₃, W(CO)(HC≡C(CH₂CH(CH₃)₂)₃, W(NO)(HC≡CH)₃, W(NO)(CH₃C≡CCH₃)₃, W(NO)(CH₃CH₂C≡CCH₂CH₃)₃, W(NO)(CH₃(CH₂)₂C≡C(CH₂)₂CH₃)₃, W(NO)(HC≡CCH₃)₃, W(NO)(HC≡CCH₂CH₃)₃, W(NO)(HC≡C(CH₂)₂CH₃)₃, W(NO)(HC≡C(CH₂)₃CH₃)₃, W(NO)(HC≡C(CH₂)₄CH₃)₃, W(NO)(CH₃C≡CCH₂CH₃)₃, W(NO)(CH₃C≡C(CH₂)₂CH₃)₃, W(NO)(CH₃C≡C(CH₂)₃CH₃)₃, W(NO)(CH₃CH₂C≡C(CH₂)₂CH₃)₃, W(NO)(HC≡CCH(CH₃)₂)₃, W(NO)(HC≡CC(CH₃)₃)₃, W(NO)(HC≡C(CH₂CH(CH₃)₂)₃, W(CH₃CN)(HC≡CH)₃, W(CH₃CN)(CH₃C≡CCH₃)₃, W(CH₃CN)(CH₃CH₂C≡CCH₂CH₃)₃, W(CH₃CN)(CH₃(CH₂)₂C≡C(CH₂)₂CH₃)₃, W(CH₃CN)(HC≡CCH₃)₃, W(CH₃CN)(HC≡CCH₂CH₃)₃, W(CH₃CN)(HC≡C(CH₂)₂CH₃)₃, W(CH₃CN)(HC≡C(CH₂)₃CH₃)₃, W(CH₃CN)(HC≡C(CH₂)₄CH₃)₃, W(CH₃CN)(CH₃C≡CCH₂CH₃)₃, W(CH₃CN)(CH₃C≡C(CH₂)₂CH₃)₃, W(CH₃CN)(CH₃C≡C(CH₂)₃CH₃)₃, W(CH₃CN)(CH₃CH₂C≡C(CH₂)₂CH₃)₃, W(CH₃CN)(HC≡CCH(CH₃)₂)₃, W(CH₃CN)(HC≡CC(CH₃)₃)₃, and W(CH₃CN)(HC≡C(CH₂CH(CH₃)₂)₃. In an embodiment of the present disclosure, the tungsten compound may include W(CO)(CH₃CH₂C≡CCH₂CH₃)₃, but may not be limited thereto.

In an embodiment of the present disclosure, the gas including the tungsten compound may further include a stabilizing agent which suppresses a pyrolysis of the tungsten compound, but may not be limited thereto. The stabilizing agent may suppress a pyrolysis of the tungsten compound by suppressing polymerization of alkyne contained in the tungsten compound. The stabilizing agent may use stabilizing agents typically used for suppressing alkyne polymerization without particular limitation, and may include, for example, a member selected from the group consisting of benzoquinone, tetramethylbenzoquinone, chloranil (2,3,5,6-tetrachloro-1,4-benzoquinone), 4-tert-butylcatechol, and 2,2-diphenyl-1-picrylhydrazyl, but may not be limited thereto.

In an embodiment of the present disclosure, if the gas including the tungsten compound further includes the stabilizing agent which suppresses the pyrolysis of the tungsten compound, the gas may have a further improved vaporization characteristic at a lower temperature and may be remarkably decreased in an amount of a pyrolysis product which does not vaporize but remains when a temperature is increased, as compared with the case where the stabilizing agent is not included.

In accordance with an embodiment of the present disclosure, the tungsten compound is a complex in which tungsten central metal is bonded to a ligand by coordinated bond with a low binding force. Thus, a dissociation of the ligand easily occurs even at a relatively low temperature and thus a deposition temperature can be decreased. Further, a neutral ligand L and alkyne separated from the tungsten central metal can be easily removed form a reaction chamber by evacuation. Thus, impurities such as carbon, nitrogen, oxygen, and the like may not remain in the as-formed tungsten-containing film.

In an embodiment of the present disclosure, the deposition method of the tungsten-containing film may further include contacting a reacting gas containing hydrogen gas, ammonia gas, oxygen (O₂) gas or ozone (O₃) gas with the substrate simultaneously or alternately with contacting the gas including the tungsten derivative compound with the substrate, but may not be limited thereto.

In an embodiment of the present disclosure, the deposition method of the tungsten-containing film may be performed by a metal organic chemical vapor deposition (MOCVD) or atomic layer deposition (ALD), but may not be limited thereto.

In an embodiment of the present disclosure, the tungsten-containing film may be formed on the surface of the substrate by contacting the reacting gas with the substrate in addition to contacting the gas including the tungsten compound with the substrate. By way of example, there may be used an atomic layer deposition (ALD) method of alternately contacting the tungsten compound-containing gas and the reacting gas with the surface of the substrate, but may not be limited thereto. By way of example, there may be used a chemical vapor deposition (CVD) method of simultaneously contacting the tungsten compound-containing gas and the reacting gas with the surface of the substrate, but may not be limited thereto.

In an ALD device or CVD device for a film deposition, the tungsten compound-containing gas according to an embodiment of the present disclosure may be contacted with the surface of the substrate by using the known method such as bubbling, a gas flow control method, a direct liquid injection method, or a liquid transfer method.

In an embodiment of the present disclosure, as the reacting gas used in the ALD and CVD methods, gases used for a semiconductor process, such as hydrogen (H₂) gas, ammonia (NH₃) gas, oxygen (O₂) gas, or ozone (O₃) gas, may be used to form a tungsten-containing film, but may not be limited thereto. By way of example, if a film is formed using hydrogen gas and/or ammonia gas by the ALD and CVD methods, a tungsten metal film with less impurities may be formed. By way of example, if a film is formed using oxygen gas or ozone gas, a tangent oxide film may be formed, but may not be limited thereto.

In a second aspect of the present disclosure, there is provided a precursor composition for depositing a tungsten-containing film, including: a tungsten compound represented by the following Chemical Formula 1:

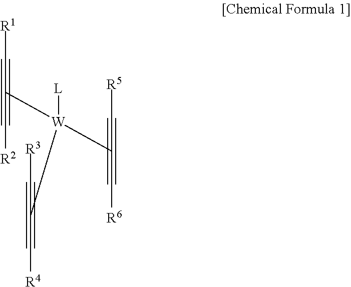

wherein in the above Chemical Formula 1,

each of R¹ to R⁶ independently includes H or a C₁₋₅ alkyl group,

L includes a non-cyclic or cyclic neutral ligand having a carbon number ranging from 0 to 5 and including 1 to 3 nitrogens or oxygens.

In an embodiment of the present disclosure, the C₁₋₅ alkyl group may include a member selected from the group consisting of a methyl group, ethyl group, n-propyl group, iso-propyl group, n-butyl group, iso-butyl group, sec-butyl group, tert-butyl group, n-pentyl group, iso-pentyl group, sec-pentyl group, tert-pentyl group, neo-pentyl group, 3-pentyl group, and isomers thereof, but may not be limited thereto.

In an embodiment of the present disclosure, the L may include a member selected from the group consisting of carbon monoxide (CO), nitrogen monoxide (NO), and acetonitrile (CH₃CN), but may not be limited thereto.

In an embodiment of the present disclosure, the tungsten compound may include a member selected from the group consisting of W(CO)(HC≡CH)₃, W(CO)(CH₃C≡CCH₃)₃, W(CO)(CH₃CH₂C≡CCH₂CH₃)₃, W(CO)(CH₃(CH₂)₂C≡C(CH₂)₂CH₃)₃, W(CO)(HC≡CCH₃)₃, W(CO)(HC≡CCH₂CH₃)₃, W(CO)(HC≡C(CH₂)₂CH₃)₃, W(CO)(HC≡C(CH₂)₃CH₃)₃, W(CO)(HC≡C(CH₂)₄CH₃)₃, W(CO)(CH₃C≡CCH₂CH₃)₃, W(CO)(CH₃C≡C(CH₂)₂CH₃)₃, W(CO)(CH₃C≡C(CH₂)₃CH₃)₃, W(CO)(CH₃CH₂C≡C(CH₂)₂CH₃)₃, W(CO)(HC≡CCH(CH₃)₂)₃, W(CO)(HC≡CC(CH₃)₃)₃, W(CO)(HC≡C(CH₂CH(CH₃)₂)₃, W(NO)(HC≡CH)₃, W(NO)(CH₃C≡CCH₃)₃, W(NO)(CH₃CH₂C≡CCH₂CH₃)₃, W(NO)(CH₃(CH₂)₂C≡C(CH₂)₂CH₃)₃, W(NO)(HC≡CCH₃)₃, W(NO)(HC≡CCH₂CH₃)₃, W(NO)(HC≡C(CH₂)₂CH₃)₃, W(NO)(HC≡C(CH₂)₃CH₃)₃, W(NO)(HC≡C(CH₂)₄CH₃)₃, W(NO)(CH₃C≡CCH₂CH₃)₃, W(NO)(CH₃C≡C(CH₂)₂CH₃)₃, W(NO)(CH₃C≡C(CH₂)₃CH₃)₃, W(NO)(CH₃CH₂C≡C(CH₂)₂CH₃)₃, W(NO)(HC≡CCH(CH₃)₂)₃, W(NO)(HC≡CC(CH₃)₃)₃, W(NO)(HC≡C(CH₂CH(CH₃)₂)₃, W(CH₃CN)(HC≡CH)₃, W(CH₃CN)(CH₃C≡CCH₃)₃, W(CH₃CN)(CH₃CH₂C≡CCH₂CH₃)₃, W(CH₃CN)(CH₃(CH₂)₂C≡C(CH₂)₂CH₃)₃, W(CH₃CN)(HC≡CCH₃)₃, W(CH₃CN)(HC≡CCH₂CH₃)₃, W(CH₃CN)(HC≡C(CH₂)₂CH₃)₃, W(CH₃CN)(HC≡C(CH₂)₃CH₃)₃, W(CH₃CN)(HC≡C(CH₂)₄CH₃)₃, W(CH₃CN)(CH₃C≡CCH₂CH₃)₃, W(CH₃CN)(CH₃C≡C(CH₂)₂CH₃)₃, W(CH₃CN)(CH₃C≡C(CH₂)₃CH₃)₃, W(CH₃CN)(CH₃CH₂C≡C(CH₂)₂CH₃)₃, W(CH₃CN)(HC≡CCH(CH₃)₂)₃, W(CH₃CN)(HC≡CC(CH₃)₃)₃, and W(CH₃CN)(HC≡C(CH₂CH(CH₃)₂)₃. In an embodiment of the present disclosure, the tungsten compound may include W(CO)(CH₃CH₂C≡CCH₂CH₃)₃, but may not be limited thereto.

In an embodiment of the present disclosure, forming a film using the precursor composition for depositing the tungsten-containing film including the tungsten compound may be performed by a metal organic chemical vapor deposition (MOCVD) or atomic layer deposition (ALD), but may not be limited thereto.

In an embodiment of the present disclosure, the precursor composition for depositing the tungsten-containing film may further include a stabilizing agent which suppresses a pyrolysis of the tungsten compound, but may not be limited thereto. By way of example, the stabilizing agent may suppress the polymerization, and may use stabilizing agents typically used for suppressing alkyne polymerization without particular limitation, and may include, for example, benzoquinone, tetramethylbenzoquinone, chloranil (2,3,5,6-tetrachloro-1,4-benzoquinone), 4-tert-butylcatechol, and 2,2-diphenyl-1-picrylhydrazyl, but may not be limited thereto. In accordance with an embodiment of the present disclosure, if the precursor composition for depositing the tungsten-containing film includes the stabilizing agent, the precursor composition may have a further improved vaporization characteristic at a lower temperature and may be remarkably decreased in an amount of a pyrolysis product which does not vaporize but remains when a temperature is increased, as compared with the case where the stabilizing agent is not included.

In accordance with an embodiment of the present disclosure, if the precursor composition for depositing the tungsten-containing film includes the stabilizing agent, the stabilizing agent having volatility similar to that of the tungsten compound may be used. If the tungsten compound and the stabilizing agent volatilize at the same ratio as the composition of a precursor composition solution, the composition of the precursor composition may be relatively uniformly maintained while the precursor composition volatilizes.

In accordance with an embodiment of the present disclosure, in the precursor composition, the tungsten compound may include W(CO)(CH₃CH₂C≡CCH₂CH₃)₃, and the stabilizing agent may include 4-tert-butylcatechol, but may not be limited thereto.

The second aspect of the present disclosure relates to a precursor composition including a tungsten compound for depositing a tungsten-containing film. Detailed description of the same parts as those of the first aspect of the present disclosure has been omitted. However, although omitted in the second aspect, the descriptions with respect to the first aspect of the present disclosure may be equally applied to the second aspect of the present disclosure.

### MODE FOR CARRYING OUT THE INVENTION

Hereinafter, the present disclosure will be explained in detail with reference to Examples. However, the following Examples are provided for understanding of the present disclosure but not intended to limit the present disclosure.

### EXAMPLE

### Preparation Example 1

### Preparation of W(CO)(CH₃CH₂C≡CCH₂CH₃)₃

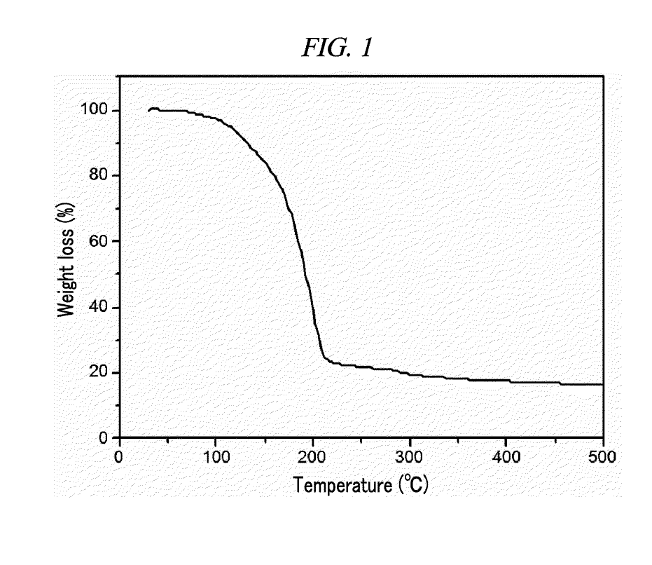

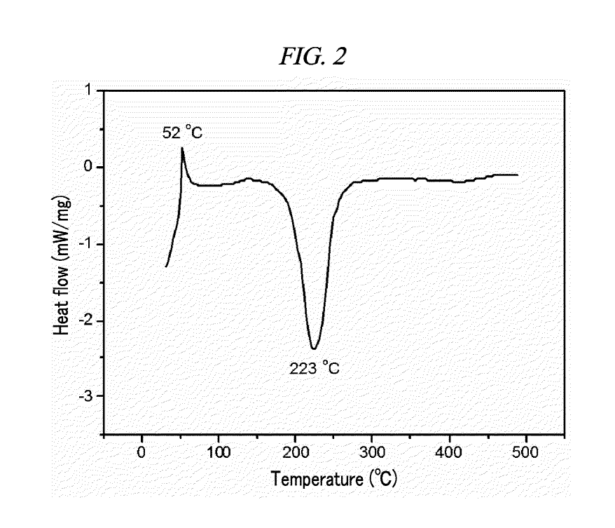

A tungsten precursor compound, tris(3-hexine)carbonyltungsten [W(CO)(CH₃CH₂C≡CCH₂CH₃)₃], was obtained by synthesis according to the known method [Journal of the American Chemical Society (1963), 85(14), 2174]. A thermogravimetric analysis and a differential scanning calorimetry were conducted for the obtained tungsten precursor compound, and the results thereof were as shown in FIG. 1 and FIG. 2.

In this regard, FIG. 1 is the thermogravimetric analysis (TGA) graph of the tungsten compound prepared according to the present Example, and FIG. 2 is the differential scanning calorimetry (DSC) graph of the tungsten compound prepared according to the present Example.

### Example 1

### Formation of Tungsten-Containing Film Using W(CO)(CH₃CH₂C≡CCH₂CH₃)₃ and Hydrogen (H₂) Gas, and Cross-Section Analysis Thereof

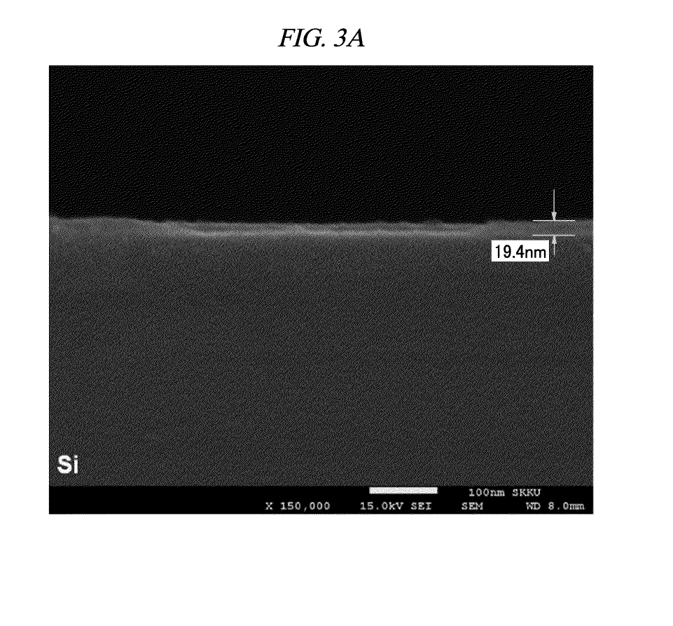

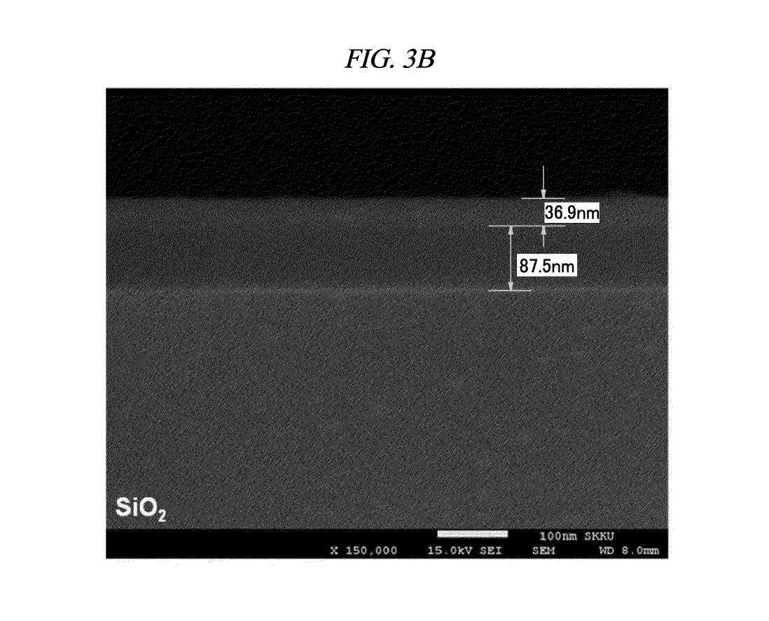

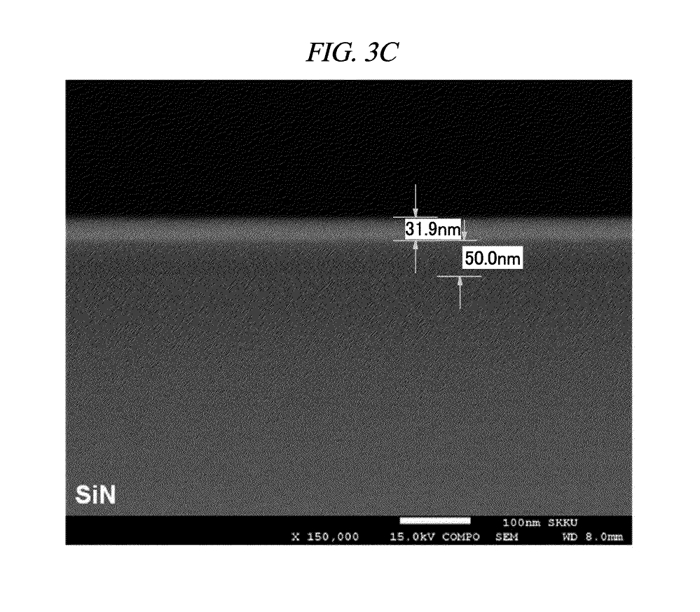

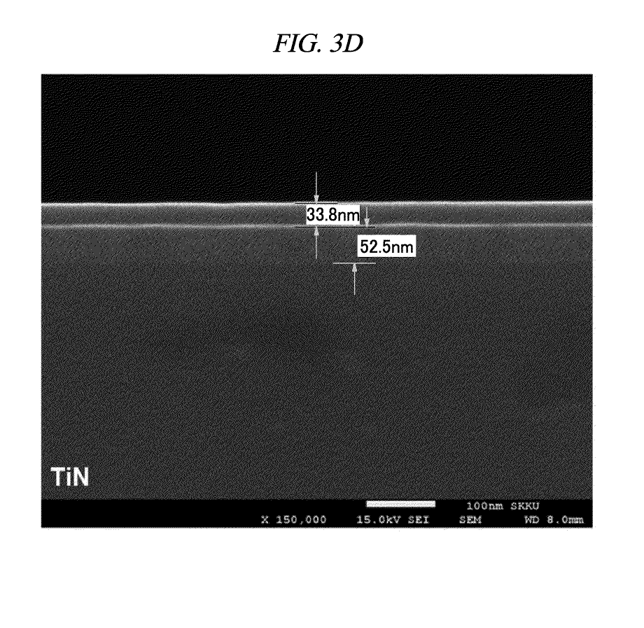

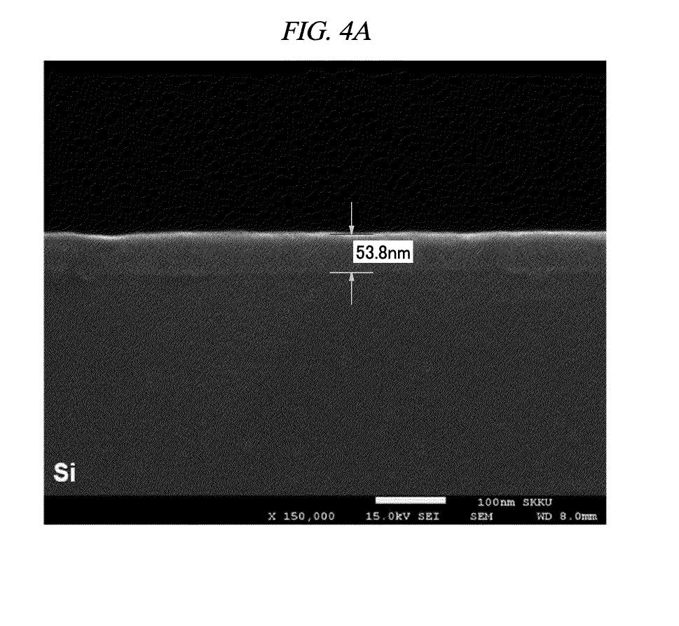

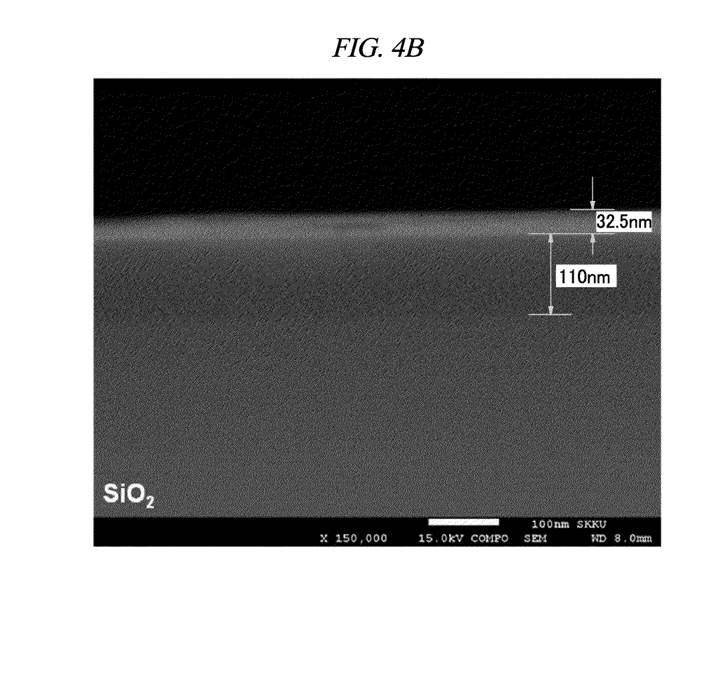

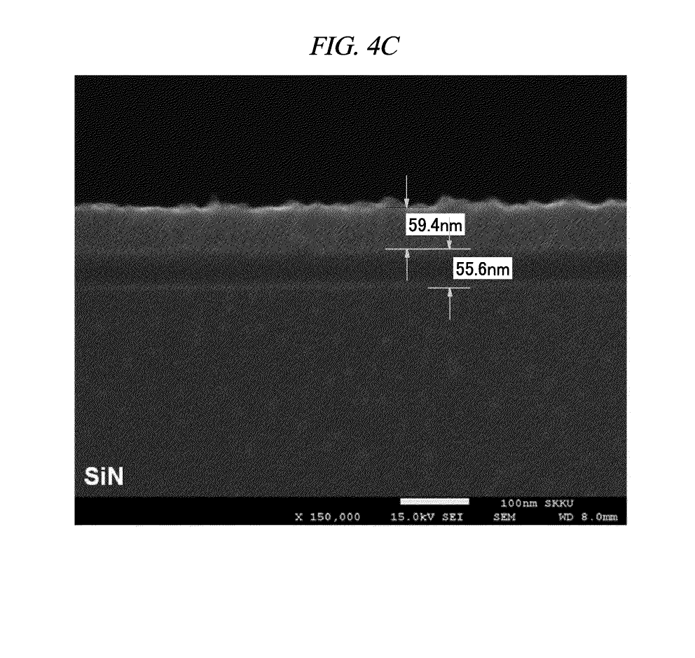

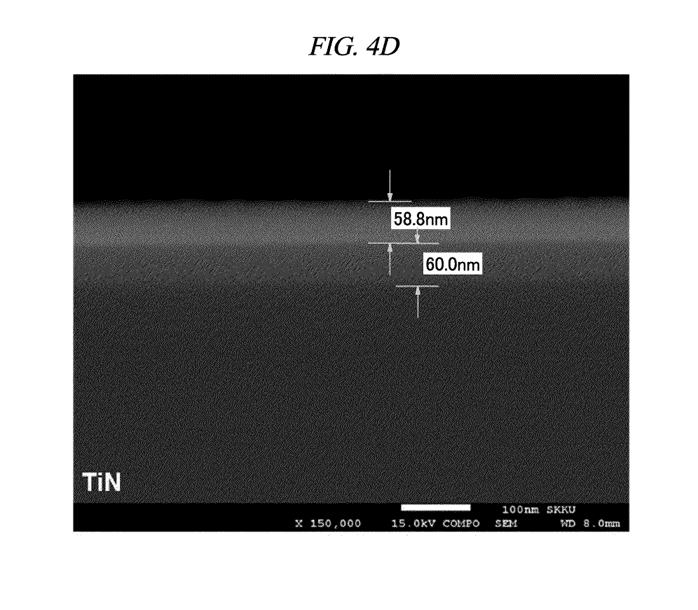

A tungsten-containing film was formed by alternately contacting the tris(3-hexine)carbonyltungsten [W(CO)(CH₃CH₂C≡CCH₂CH₃)₃] gas obtained in Preparation Example 1 and hydrogen (H₂) gas with a surface of a substrate. As the substrate, a silicon (Si) wafer, a wafer including a silicon oxide (SiO₂) film coated to a thickness of 100 nm on a silicon substrate, a wafer including a silicon nitride (SiN) film coated to a thickness of 50 nm on a silicon substrate, and a wafer including a titanium nitride (TiN) film coated to a thickness of 50 nm on a silicon substrate were used, respectively. Herein, the substrate was heated to a temperature of 325° C. and 350° C., respectively. The compound obtained in Preparation Example 1 was put into a stainless steel container, and while the container was heated at a temperature of 70° C., the compound obtained in Preparation Example 1 was vaporized using an argon gas having a flow rate of 60 sccm as a carrier gas. A working pressure in a reactor in which a gas flows in a direction horizontal to the flat surface of the substrate was adjusted to 0.5 torr, and the tungsten precursor gas and a hydrogen gas were alternately brought into contact with the substrate placed within an atomic layer deposition chamber. The hydrogen gas was set to flow at 60 sccm. A cross section of a tungsten-containing film formed by repeating 300 times gas supply cycle including: supplying the compound gas obtained in Preparation Example 1 for 20 seconds; supplying Ar gas for 10 seconds; supplying hydrogen gas for 10 seconds; and supplying Ar gas for 10 seconds, was observed with a scanning electron microscope (SEM), and the result thereof was as shown in FIG. 3 and FIG. 4.

In this regard, FIG. 3A to FIG. 3D provide cross-sectional scanning electron microscopic images of the tungsten-containing films formed at a temperature of 325° C. of the substrate according to the present Example, and FIG. 4A to FIG. 4D provide cross-sectional scanning electron microscopic images of the tungsten-containing films formed at a temperature of 350° C. of the substrate according to the present Example. As can be seen from FIG. 3A to FIG. 3D and FIG. 4A to FIG. 4D, tungsten-containing films each having a generally flat surface were formed on the silicon, silicon oxide, silicon nitride and titanium nitride substrates, respectively, at each temperature of 325° C. and 350° C.

### Example 2

### Elemental Analysis of Tungsten-Containing Film Formed Using W(CO)(CH₃CH₂C≡CCH₂CH₃)₃ and Hydrogen (H₂) or Ammonia (NH₃) Gas

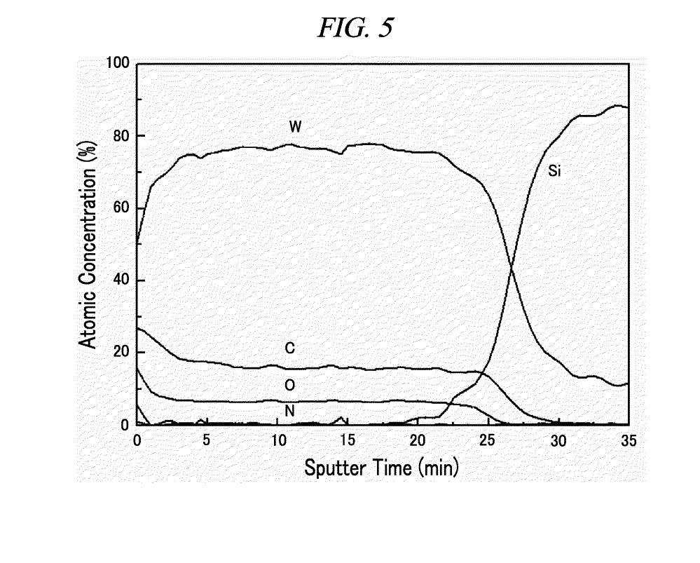

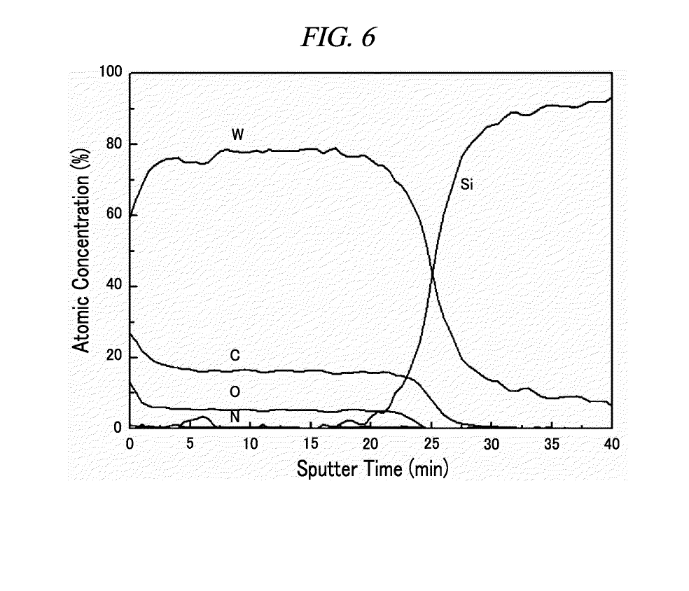

A silicon (Si) substrate was heated to a temperature 350° C., and a tungsten compound W(CO)(CH₃CH₂C≡CCH₂CH₃)₃ obtained in Preparation Example 1 was put into a stainless steel container. Then, while the container was heated at a temperature of 70° C., the tungsten-containing compound obtained in Preparation Example 1 was vaporized using an argon gas having a flow rate of 60 sccm as a carrier gas. A working pressure in a reactor was adjusted to 0.5 torr, and the tungsten compound gas obtained in Preparation Example 1 and a hydrogen gas or an ammonia gas were alternately brought into contact with the silicon substrate placed within the reactor as described in Example 1. The hydrogen gas or the ammonia gas was set to flow at a flow rate of 500 sccm. A tungsten-containing film was formed by repeating 300 times gas supply cycle including: supplying the compound gas obtained in Preparation Example 1 for 10 seconds; supplying Ar gas for 10 seconds; supplying hydrogen gas or ammonia gas for 20 seconds; and supplying Ar gas for 10 seconds. Then, contents of carbon, nitrogen, oxygen, and tungsten depending upon a depth of the formed tungsten-containing film were analyzed with Auger spectroscopy. The result thereof was as shown in FIG. 5 and FIG. 6.

In this regard, FIG. 5 provides the Auger analysis result of the tungsten-containing film formed using the hydrogen (H₂) gas at a temperature of 350° C. of the substrate according to the present Example, and FIG. 6 provides the Auger analysis result of the tungsten-containing film formed using the ammonia (NH₃) gas at a temperature of 350° C. of the substrate according to the present Example. As can be seen from FIG. 5 and FIG. 6, the tungsten-containing films each having the tungsten content of about 75% were respectively formed on the silicon substrates in both of the case where the hydrogen gas was used and the case where the ammonia gas was used.

### Example 3

### Thermogravimetric Analysis of Precursor Composition Including W(CO)(CH₃CH₂C≡CCH₂CH₃)₃ for Depositing Tungsten-Containing Film Added with 4-Tert-Butylcatechol (TBC) as Stabilizing Agent

A thermogravimetric analysis (TGA) was conducted to a precursor composition for depositing a tungsten-containing film in which 3,000 ppm of 4-tert-butylcatechol (TBC) was added to the tungsten compound W(CO)(CH₃CH₂C≡CCH₂CH₃)₃ prepared in Preparation Example 1 in order to improve stability of a precursor composition used for CVD or ALD.

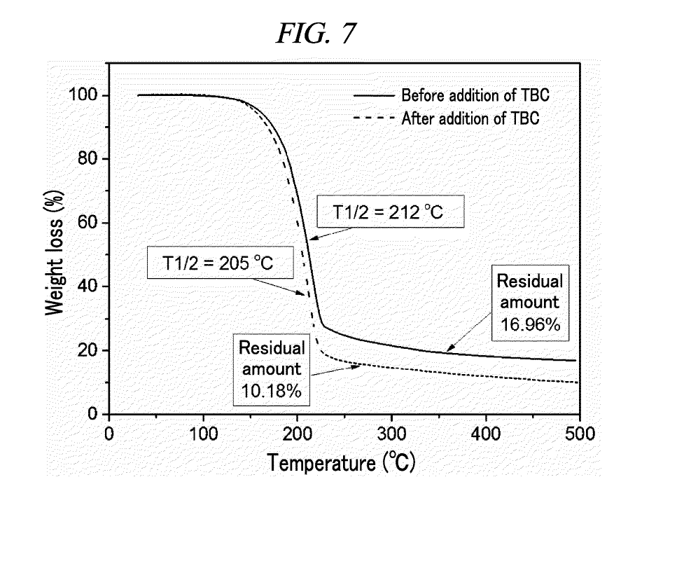

Herein, about 5 mg of a sample of the precursor composition for depositing a tungsten-containing film was put into an alumina sample container. Then, a thermogravimetric analysis was conducted to the sample heated to 500° C. by a heating rate of 10° C./min. The measurement result thereof was as shown in FIG. 7.

As shown in FIG. 7, from the TGA graph for a precursor composition for depositing the tungsten-containing film including the TBC stabilizing agent, it can be seen that T₁₁₂ (a temperature when a weight of the sample was decreased according to a temperature to reach ½ of the original weight of the sample) was 205° C., which was lower by 7° C. than T₁₁₂ (212° C.) of the sample without including the TBC. Further, it can be seen that a residual amount after the precursor composition for depositing the tungsten-containing film including the TBC stabilizing agent vaporized was 10.18%, which was greatly reduced as compared with 16.96% as a residual amount of the sample without including the TBC. From the above-described result, it can be seen that the precursor composition for depositing the tungsten-containing film including the TBC stabilizing agent had a further improved vaporization characteristic at a lower temperature and was remarkably decreased in an amount of a pyrolysis product which did vaporize but remained when a temperature was increased. Therefore, if the precursor composition for depositing the tungsten-containing film including the stabilizing agent is used in order to form the tungsten-containing film on the substrate by the CVD or ALD method, the composition can be thermally stabilized, and, thus, the tungsten compound precursor can be more efficiently transferred to the surface of the substrate.

If the tungsten-containing film is formed using the precursor composition including a stabilizing agent for depositing a tungsten-containing film, the tungsten-containing film can be formed by the same method as Examples 1 and 2 except that the precursor composition including TBC for depositing the tungsten-containing film is put into a stainless steel container. The stainless steel container accommodating the precursor composition including the stabilizing agent (for example, TBC) for depositing a tungsten-containing film may be heated at a temperature of 70° C. as described in Examples 1 and 2, or may be heated at a lower temperature selected from the range of from about 63° C. to about 70° C., but may not be limited thereto.

The above description of the present disclosure is provided for the purpose of illustration, and it would be understood by those skilled in the art that various changes and modifications may be made without changing technical conception and essential features of the present disclosure. Thus, it is clear that the above-described Examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A deposition method of a tungsten-containing film using a tungsten compound, comprising contacting a gas including the tungsten compound represented by the following Chemical Formula 1 with a surface of a substrate: 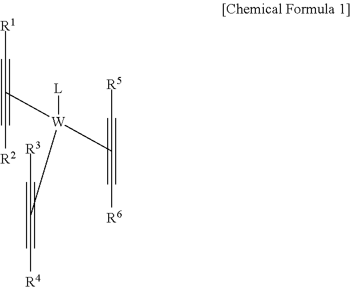
wherein in the formula 1,
each of R¹ to R⁶ independently includes H or a C₁₋₅ alkyl group,
L includes a non-cyclic or cyclic neutral ligand having a carbon number ranging from 0 to 5 and including 1 to 3 nitrogens or oxygens.

2. The deposition method of the tungsten-containing film of claim 1,
wherein L includes a member selected from the group consisting of carbon oxide (CO), nitrogen monoxide (NO), and acetonitrile (CH₃CN).

3. The deposition method of the tungsten-containing film of claim 1,
wherein the tungsten compound includes a member selected from the group consisting of W(CO)(HC≡CH)₃, W(CO)(CH₃C≡CCH₃)₃, W(CO)(CH₃CH₂C≡CCH₂CH₃)₃, W(CO)(CH₃(CH₂)₂C≡C(CH₂)₂CH₃)₃, W(CO)(HC≡CCH₃)₃, W(CO)(HC≡CCH₂CH₃)₃, W(CO)(HC≡C(CH₂)₂CH₃)₃, W(CO)(HC≡C(CH₂)₃CH₃)₃, W(CO)(HC≡C(CH₂)₄CH₃)₃, W(CO)(CH₃C≡CCH₂CH₃)₃, W(CO)(CH₃C≡C(CH₂)₂CH₃)₃, W(CO)(CH₃C≡C(CH₂)₃CH₃)₃, W(CO)(CH₃CH₂C≡C(CH₂)₂CH₃)₃, W(CO)(HC≡CCH(CH₃)₂)₃, W(CO)(HC≡CC(CH₃)₃)₃, W(CO)(HC≡C(CH₂CH(CH₃)₂)₃, W(NO)(HC≡CH)₃, W(NO)(CH₃C≡CCH₃)₃, W(NO)(CH₃CH₂C≡CCH₂CH₃)₃, W(NO)(CH₃(CH₂)₂C≡C(CH₂)₂CH₃)₃, W(NO)(HC≡CCH₃)₃, W(NO)(HC≡CCH₂CH₃)₃, W(NO)(HC≡C(CH₂)₂CH₃)₃, W(NO)(HC≡C(CH₂)₃CH₃)₃, W(NO)(HC≡C(CH₂)₄CH₃)₃, W(NO)(CH₃C≡CCH₂CH₃)₃, W(NO)(CH₃C≡C(CH₂)₂CH₃)₃, W(NO)(CH₃C≡C(CH₂)₃CH₃)₃, W(NO)(CH₃CH₂C≡C(CH₂)₂CH₃)₃, W(NO)(HC≡CCH(CH₃)₂)₃, W(NO)(HC≡CC(CH₃)₃)₃, W(NO)(HC≡C(CH₂CH(CH₃)₂)₃, W(CH₃CN)(HC≡CH)₃, W(CH₃CN)(CH₃C≡CCH₃)₃, W(CH₃CN)(CH₃CH₂C≡CCH₂CH₃)₃, W(CH₃CN)(CH₃(CH₂)₂C≡C(CH₂)₂CH₃)₃, W(CH₃CN)(HC≡CCH₃)₃, W(CH₃CN)(HC≡CCH₂CH₃)₃, W(CH₃CN)(HC≡C(CH₂)₂CH₃)₃, W(CH₃CN)(HC≡C(CH₂)₃CH₃)₃, W(CH₃CN)(HC≡C(CH₂)₄CH₃)₃, W(CH₃CN)(CH₃C≡CCH₂CH₃)₃, W(CH₃CN)(CH₃C≡C(CH₂)₂CH₃)₃, W(CH₃CN)(CH₃C≡C(CH₂)₃CH₃)₃, W(CH₃CN)(CH₃CH₂C≡C(CH₂)₂CH₃)₃, W(CH₃CN)(HC≡CCH(CH₃)₂)₃, W(CH₃CN)(HC≡CC(CH₃)₃)₃, and W(CH₃CN)(HC≡C(CH₂CH(CH₃)₂)₃.

4. The deposition method of the tungsten-containing film of claim 1,
wherein the tungsten compound includes W(CO)(CH₃CH₂C≡CCH₂CH₃)₃.

5. The deposition method of the tungsten-containing film of claim 1,
wherein the deposition method of the tungsten-containing film further comprises contacting a reacting gas including hydrogen gas, ammonia gas, oxygen gas or ozone gas with the substrate simultaneously or alternately with contacting the gas including the tungsten compound with the substrate.

6. The deposition method of the tungsten-containing film of claim 1,
wherein the deposition method of the tungsten-containing film includes performing the deposition method by a metal organic chemical vapor deposition (MOCVD) or atomic layer deposition (ALD).

7. The deposition method of the tungsten-containing film of claim 1,
wherein the gas including the tungsten compound further includes a stabilizing agent which suppresses a pyrolysis of the tungsten compound.

8. The deposition method of the tungsten-containing film of claim 7,
wherein the stabilizing agent includes a member selected from the group consisting of benzoquinone, tetramethylbenzoquinone, chloranil (2,3,5,6-tetrachloro-1,4-benzoquinone), 4-tert-butylcatechol, and 2,2-diphenyl-1-picrylhydrazyl.

9. A precursor composition for depositing a tungsten-containing film, comprising a tungsten compound represented by the following Chemical Formula 1: 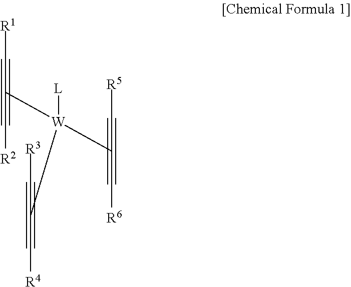
wherein in the formula 1,
R¹ to R⁶ and L is the same as defined above in claim 1.

10. The precursor composition for depositing the tungsten-containing film of claim 9,
wherein L includes a member selected from the group consisting of carbon oxide (CO), nitrogen monoxide (NO), and acetonitrile (CH₃CN).

11. The precursor composition for depositing the tungsten-containing film of claim 9,
wherein the tungsten compound includes a member selected from the group consisting of W(CO)(HC≡CH)₃, W(CO)(CH₃C≡CCH₃)₃, W(CO)(CH₃CH₂C≡CCH₂CH₃)₃, W(CO)(CH₃(CH₂)₂C≡C(CH₂)₂CH₃)₃, W(CO)(HC≡CCH₃)₃, W(CO)(HC≡CCH₂CH₃)₃, W(CO)(HC≡C(CH₂)₂CH₃)₃, W(CO)(HC≡C(CH₂)₃CH₃)₃, W(CO)(HC≡C(CH₂)₄CH₃)₃, W(CO)(CH₃C≡CCH₂CH₃)₃, W(CO)(CH₃C≡C(CH₂)₂CH₃)₃, W(CO)(CH₃C≡C(CH₂)₃CH₃)₃, W(CO)(CH₃CH₂C≡C(CH₂)₂CH₃)₃, W(CO)(HC≡CCH(CH₃)₂)₃, W(CO)(HC≡CC(CH₃)₃)₃, W(CO)(HC≡C(CH₂CH(CH₃)₂)₃, W(NO)(HC≡CH)₃, W(NO)(CH₃C≡CCH₃)₃, W(NO)(CH₃CH₂C≡CCH₂CH₃)₃, W(NO)(CH₃(CH₂)₂C≡C(CH₂)₂CH₃)₃, W(NO)(HC≡CCH₃)₃, W(NO)(HC≡CCH₂CH₃)₃, W(NO)(HC≡C(CH₂)₂CH₃)₃, W(NO)(HC≡C(CH₂)₃CH₃)₃, W(NO)(HC≡C(CH₂)₄CH₃)₃, W(NO)(CH₃C≡CCH₂CH₃)₃, W(NO)(CH₃C≡C(CH₂)₂CH₃)₃, W(NO)(CH₃C≡C(CH₂)₃CH₃)₃, W(NO)(CH₃CH₂C≡C(CH₂)₂CH₃)₃, W(NO)(HC≡CCH(CH₃)₂)₃, W(NO)(HC≡CC(CH₃)₃)₃, W(NO)(HC≡C(CH₂CH(CH₃)₂)₃, W(CH₃CN)(HC≡CH)₃, W(CH₃CN)(CH₃C≡CCH₃)₃, W(CH₃CN)(CH₃CH₂C≡CCH₂CH₃)₃, W(CH₃CN)(CH₃(CH₂)₂C≡C(CH₂)₂CH₃)₃, W(CH₃CN)(HC≡CCH₃)₃, W(CH₃CN)(HC≡CCH₂CH₃)₃, W(CH₃CN)(HC≡C(CH₂)₂CH₃)₃, W(CH₃CN)(HC≡C(CH₂)₃CH₃)₃, W(CH₃CN)(HC≡C(CH₂)₄CH₃)₃, W(CH₃CN)(CH₃C≡CCH₂CH₃)₃, W(CH₃CN)(CH₃C≡C(CH₂)₂CH₃)₃, W(CH₃CN)(CH₃C≡C(CH₂)₃CH₃)₃, W(CH₃CN)(CH₃CH₂C≡C(CH₂)₂CH₃)₃, W(CH₃CN)(HC≡CCH(CH₃)₂)₃, W(CH₃CN)(HC≡CC(CH₃)₃)₃, and W(CH₃CN)(HC≡C(CH₂CH(CH₃)₂)₃.

12. The precursor composition for depositing the tungsten-containing film of claim 9,
wherein the tungsten compound includes W(CO)(CH₃CH₂C≡CCH₂CH₃)₃.

13. The precursor composition for depositing the tungsten-containing film of claim 9, further comprising:
a stabilizing agent which suppresses a pyrolysis of the tungsten compound.

14. The precursor composition for depositing the tungsten-containing film of claim 13,
wherein the stabilizing agent includes a member selected from the group consisting of benzoquinone, tetramethylbenzoquinone, chloranil (2,3,5,6-tetrachloro-1,4-benzoquinone), 4-tert-butylcatechol, and 2,2-diphenyl-1-picrylhydrazyl.

15. The precursor composition for depositing the tungsten-containing film of claim 13,
wherein the tungsten compound includes W(CO)(CH₃CH₂C≡CCH₂CH₃)₃, and the stabilizing agent includes 4-tert-butylcatechol.
